(19) United States
(12) Patent Application Publication
(10) Pub. No.: US 2024/0282769 A1
(43) Pub. Date: Aug. 22, 2024

(54) Common source transistor apparatus

(71) Applicant: REALTEK SEMICONDUCTOR CORPORATION, Hsinchu (TW)

(72) Inventors: HUI-MIN HUANG, Hsinchu (TW); CHIEH-PIN CHANG, Hsinchu (TW); LI-CHENG CHU, Hsinchu (TW); CHUN-CHIEN TSAI, Hsinchu (TW); LEAF CHEN, Hsinchu (TW)

(21) Appl. No.: 18/443,362

(22) Filed: Feb. 16, 2024

(30) Foreign Application Priority Data
Feb. 21, 2023 (TW) 112106290

(51) Int. Cl. H01L 27/088

(52) U.S. Cl. CPC H01L 27/088

(57) ABSTRACT

The present disclosure discloses a common source transistor apparatus. The common source transistor unit includes a diffusion area, poly-silicon gates and a source/bulk ring. The diffusion area includes source/bulk areas and drain areas. Each of the poly-silicon gates traverses the diffusion areas between one of the source/bulk areas and one of the drain areas and includes a low-voltage gate part, a first high-voltage gate part and a second high-voltage gate part. The low-voltage gate part includes 2N low-voltage poly-silicon gates. Each of the first and the second high-voltage gate parts is disposed at a side of the low-voltage gate part having one of the source/bulk areas disposed therebetween and includes N+1 high-voltage poly-silicon gates. The source/bulk ring surrounds the diffusion and the poly-silicon gates and is coupled to the source/bulk area. An isolation ring surrounds the common source transistor unit. A substrate ring surrounds the isolation ring.

### BACKGROUND OF THE INVENTION

### 1. Field of the Invention

The present disclosure relates to a common source transistor apparatus.

### 2. Description of Related Art

In recent years, applications of high-voltage integrated circuits having a higher operation voltage gradually increase. As a result, devices that integrate high voltage transistors having the higher operation voltage and low voltage transistors having a lower operation voltage are presently accordingly.

In conventional designs, the common source high voltage transistors and the low voltage transistors are disposed independently in different areas and are further electrically coupled through the sources thereof to avoid the influence of different operation voltages. However, such a design not only increases the area of the components but also causes an uneven temperature distribution of the circuit since a higher temperature occurs at the location of the circuit having the high voltage transistors disposed thereon when a large amount of the high voltage transistors and the low voltage transistor are presented.

### SUMMARY OF THE INVENTION

In consideration of the problem of the prior art, an object of the present disclosure is to provide a common source transistor apparatus.

The present invention discloses a common source transistor apparatus that includes a common source transistor unit, an isolation ring and a substrate ring. The common source transistor unit includes a diffusion area, a plurality of poly-silicon gates and a source/bulk ring. The diffusion area includes a plurality of source/bulk areas and a plurality of drain areas disposed in an interlaced manner. The poly-silicon gates traverse laterally across the diffusion area and each is disposed between one of the source/bulk areas and one of the drain areas. The poly-silicon gates include a low-voltage gate part, a first high-voltage gate part, a second high-voltage gate part and a source/bulk ring. The low-voltage gate part includes 2N low voltage poly-silicon gates disposed neighboring to each other. The first high-voltage gate part is disposed at a first side of the low-voltage gate part and has one of the source/bulk areas disposed between the first high-voltage gate part and the low-voltage gate part. The second high-voltage gate part is disposed at a second side of the low-voltage gate part and has one of the source/bulk areas disposed between the second high-voltage gate part and the low-voltage gate part. Each of the first high-voltage gate part and the second high-voltage gate part includes N+1 high-voltage poly-silicon gates disposed neighboring to each other. The source/bulk ring is disposed to surround the diffusion area and the poly-silicon gates and is electrically coupled to the source/bulk areas to receive a source/bulk voltage. The isolation ring is disposed to surround the common source transistor unit to receive an isolation voltage. The substrate ring disposed to surround the isolation ring to receive a substrate voltage.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a layout diagram of a common source transistor apparatus according to an embodiment of the present invention.

FIG. 2 illustrates a cross-sectional view of the common source transistor apparatus from a direction A in FIG. 1 according to an embodiment of the present invention.

FIG. 3 is an enlarged diagram of the source/bulk ring, the isolation ring and the substrate ring at the left side of FIG. 2 according to an embodiment of the present invention.

FIG. 4 illustrates an equivalent circuit diagram of the common source transistor apparatus in FIG. 1 and FIG. 2 according to an embodiment of the present invention.

FIG. 5 illustrates a layout diagram of a common source transistor apparatus according to an embodiment of the present invention.

FIG. 6 illustrates a layout diagram of a common source transistor apparatus that includes a low voltage transistor and a high voltage transistor disposed independently according to some approaches.

### DETAILED DESCRIPTION OF THE PREFERRED EMBODIMENTS

An aspect of the present invention is to provide a common source transistor apparatus to integrate poly-silicon gates of low voltage transistors and high voltage transistors in the same diffusion area so as to be surrounded by a source/bulk ring to form a common source transistor unit. Only one isolation ring and one substrate ring are required to surround the common source transistor unit. As a result, such a configuration not only has a smaller area but also has a more even temperature distribution.

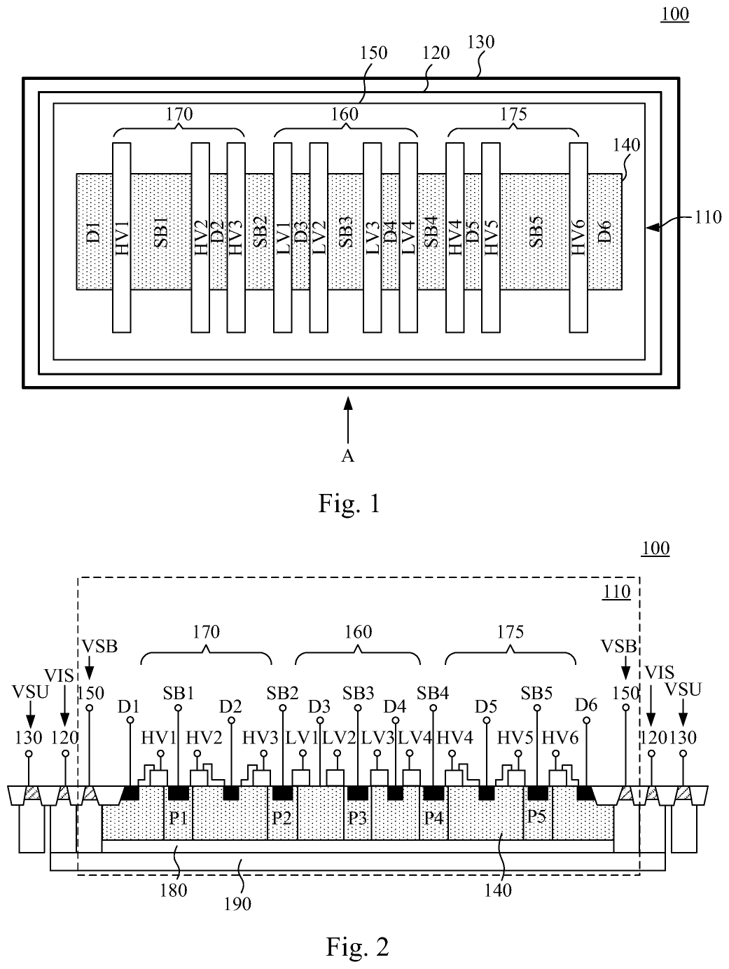

Reference is now made to FIG. 1 and FIG. 2 at the same time. FIG. 1 illustrates a layout diagram of a common source transistor apparatus 100 according to an embodiment of the present invention. FIG. 2 illustrates a cross-sectional view of the common source transistor apparatus 100 from a direction A in FIG. 1 according to an embodiment of the present invention.

The common source transistor apparatus 100 includes a common source transistor unit 110, an isolation ring 120 and a substrate ring 130.

The common source transistor unit 110 includes a diffusion area 140, a plurality of poly-silicon gates LV1˜LV4 and HV1˜HV6 and a source/bulk ring 150.

In FIG. 1 and FIG. 2, the diffusion area 140 is illustrated as a dotted area and includes a plurality of source/bulk areas SB1˜SB5 and a plurality of the drain areas D1˜D6 disposed in an interlaced manner.

For the source/bulk areas SB1˜SB5 and the drain areas D1˜D6 in FIG. 1, labels of these areas are presented on the corresponding locations of these areas. In FIG. 2, the source/bulk areas SB1˜SB5 and the drain areas D1˜D6 are illustrated as black blocks. The labels of these areas are presented on contact locations, which are used to receive voltages, of these areas. It is appreciated that in FIG. 2, the heights of these contact locations are illustrated in order to be distinguished from each other easily. The actual heights of these contact locations can be configured according to practical requirements.

The diffusion area 140 corresponds to a first type dopant. Each of the source/bulk areas SB1˜SB5 and the drain areas D1˜D6 is an ion implantation area corresponding to the first type dopant and is disposed in doping areas P1˜P5 included by the diffusion area 140 and corresponding to a second type dopant.

The poly-silicon gates LV1˜LV4 and HV1˜HV6 traverse laterally across the diffusion area 140 and each is disposed between one of the source/bulk areas SB1˜SB5 and one of the drain areas D1˜D6.

Take the poly-silicon gates HV1˜HV3 and the poly-silicon gates LV1˜LV2 at the left side of FIG. 1 and FIG. 2 as an example, the poly-silicon gate HV1 is disposed between the drain area D1 and the source/bulk area SB1. The poly-silicon gate HV2 is disposed between the source/bulk area SB1 and the drain area D2. The poly-silicon gate HV3 is disposed between the drain area D2 and source/bulk area SB2. The poly-silicon gate LV1 is disposed between the source/bulk area SB2 and the drain area D3. The poly-silicon gate LV2 is disposed between the drain area D3 and source/bulk area SB3.

Take the poly-silicon gates HV4˜HV6 and the poly-silicon gates LV3˜LV4 at the right side of FIG. 1 and FIG. 2 as an example, the poly-silicon gate LV3 is disposed between the source/bulk area SB3 and the drain area D4. The poly-silicon gate LV4 is disposed between the drain area D4 and source/bulk area SB4. The poly-silicon gate HV4 is disposed between the source/bulk area SB4 and the drain area D5. The poly-silicon gate HV5 is disposed between the drain area D5 and source/bulk area SB5. The poly-silicon gate HV6 is disposed between the source/bulk area SB5 and the drain area D6.

The poly-silicon gates LV1˜LV4 and HV1˜HV6 includes a low-voltage gate part 160, a first high-voltage gate part 170 and a second high-voltage gate part 175.

The low-voltage gate part 160 includes 2N low voltage poly-silicon gates disposed neighboring to each other. In the present embodiment, N is 2. The four low voltage poly-silicon gates included by the low-voltage gate part 160 correspond to the poly-silicon gates LV1˜LV4.

The first high-voltage gate part 170 is disposed at a first side of the low-voltage gate part 160 and has one of the source/bulk areas disposed between the first high-voltage gate part 170 and the low-voltage gate part 160. The second high-voltage gate part 175 is disposed at a second side of the low-voltage gate part 160 and has one of the source/bulk areas disposed between the second high-voltage gate part 175 and the low-voltage gate part 160. Each of the first high-voltage gate part 170 and the second high-voltage gate part 175 includes N+1 high-voltage poly-silicon gates disposed neighboring to each other.

In the present embodiment, N+1=3. The three high voltage poly-silicon gates included by the first high-voltage gate part 170 correspond to the poly-silicon gates HV1˜HV3 and the three high voltage poly-silicon gates included by the second high-voltage gate part 175 correspond to the poly-silicon gates HV4˜HV6. The poly-silicon gates HV1˜HV3 included by the first high-voltage gate part 170 have the source/bulk area SB2 disposed against the low-voltage gate part 160. The poly-silicon gates HV4˜HV6 included by the second high-voltage gate part 175 have the source/bulk area SB4 disposed against the low-voltage gate part 160.

The source/bulk ring 150 are disposed to surround the diffusion area 140 and the poly-silicon gates LV1˜LV4 and HV1˜HV6. In FIG. 1 and FIG. 2, in order to keep the figure simple, the physical connection between the source/bulk ring 150 and the source/bulk areas SB1˜SB5 are not illustrated. However, the source/bulk ring 150 are actually electrically coupled to the source/bulk areas SB1˜SB5 to receive the source/bulk voltage VSB simultaneously.

The isolation ring 120 is disposed to surround the source/bulk ring 150 to receive an isolation voltage VIS. The substrate ring 130 is disposed to surround the isolation ring 120 to receive a substrate voltage VSU. The isolation ring 120 and the substrate ring 130 together reduce the probability that the internal configuration (i.e., the diffusion area 140, the poly-silicon gates LV1˜LV4 and HV1˜HV6 and the source/bulk ring 150) of the common source transistor apparatus 100 is influenced by external interference.

In the configuration described above, the diffusion area 140 is formed on a well area 180. The well area 180, the source/bulk ring 150 and the isolation ring 120 are formed on a substrate 190. The substrate ring 130 is disposed outside of the substrate 190. In an embodiment, the substrate 190 corresponds to the first type dopant. The well area 180 corresponds to the second type dopant.

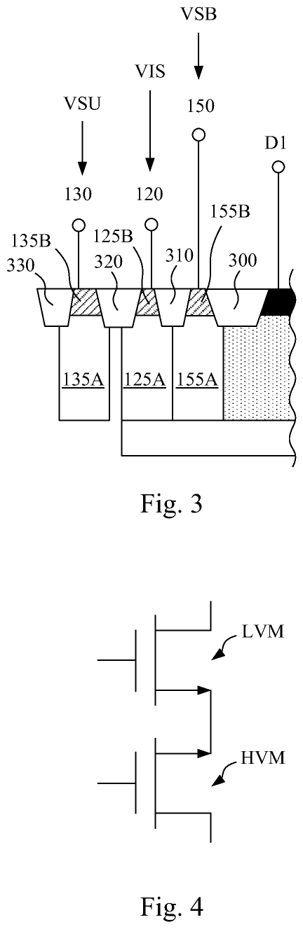

Reference is now made to FIG. 3. FIG. 3 is an enlarged diagram of the source/bulk ring 150, the isolation ring 120 and the substrate ring 130 at the left side of FIG. 2 according to an embodiment of the present invention.

In an embodiment, the source/bulk ring 150 includes a bottom part 155A and a planting part 155B disposed above the bottom part 155A. The isolation ring 120 includes a bottom part 125A and a planting part 125B disposed above the bottom part 125A. The substrate ring 130 includes a bottom part 135A and a planting part 135B disposed above the bottom part 135A.

The bottom part 155A and the planting part 155B of the source/bulk ring 150 and the bottom part 135A and the planting part 135B of the substrate ring 130 correspond to the second type dopant. The bottom part 125A and the planting part 125B of the isolation ring 120 correspond to the first type dopant.

An isolation structure is disposed at each of the two sides of each of the planting part 155A, 125A and 135A of the source/bulk ring 150, the isolation ring 120 and the substrate ring 130. The isolation structure 300 and the isolation structure 310 are disposed at the two sides of the planting part 155A. The isolation structure 310 and the isolation structure 320 are disposed at the two sides of the planting part 125A. The isolation structure 320 and the isolation structure 330 are disposed at the two sides of the planting part 135A. The isolation structures 300˜330 are configured to keep the planting part 155A, 125A and 135A electrically isolated from each other.

It is appreciated that each of the first type dopant and the second type dopant is one of a P-type dopant and an N-type dopant. In an embodiment, the first type dopant is the N-type dopant and the second type dopant is the P-type dopant. However, the present invention is not limited thereto.

Reference is now made to FIG. 4. FIG. 4 illustrates an equivalent circuit diagram of the common source transistor apparatus 100 in FIG. 1 and FIG. 2 according to an embodiment of the present invention.

The low-voltage gate part 160 in the common source transistor apparatus 100 forms a low voltage transistor LVM together with the corresponding source/bulk areas SB2˜SB4 and the drain areas D3˜D4. The first high-voltage gate part 170 and the second high-voltage gate part 175 form a high voltage transistor HVM together with the corresponding source/bulk areas SB1˜SB2 and SB4˜SB5 and the drain areas D1˜D2 and D5˜D6. The low voltage transistor LVM and the high voltage transistor HVM share the source.

Each of the low voltage transistor LVM and the high voltage transistor HVM has a corresponding operation voltage. In a numerical example, the low voltage transistor LVM has an operation voltage of 5 volts. The high voltage transistor HVM has an operation voltage of 20 volts. In an embodiment, the amount of the source/bulk voltage VSB, the isolation voltage VIS and the substrate voltage VSU correspond to the operation voltage of the high voltage transistor HVM.

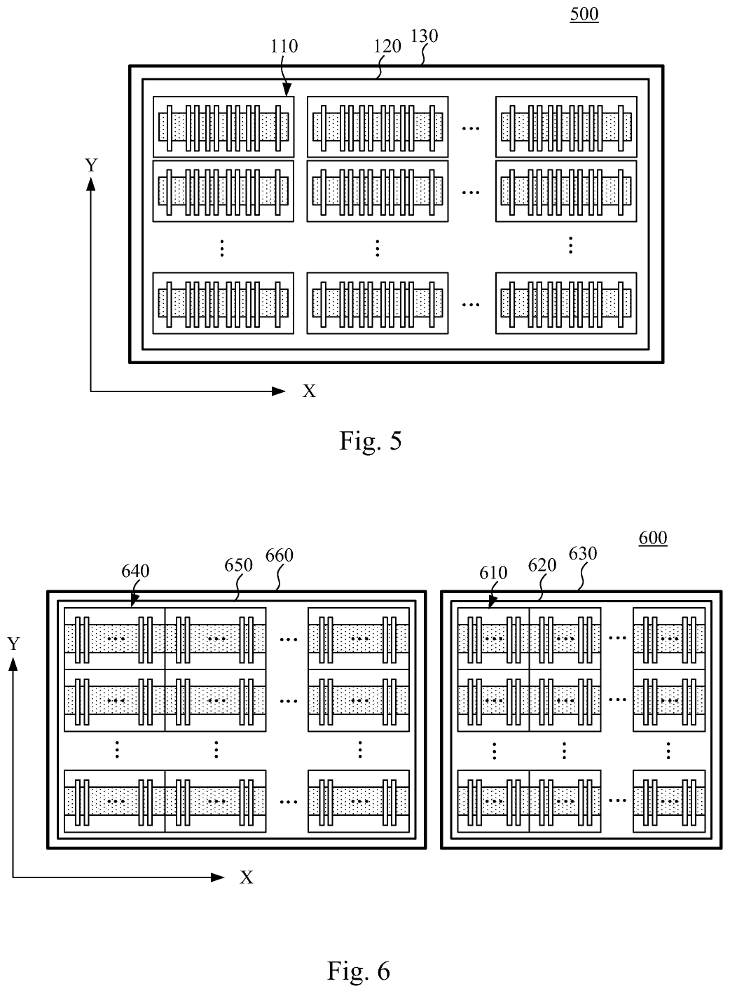

Reference is now made to FIG. 5. FIG. 5 illustrates a layout diagram of a common source transistor apparatus 500 according to an embodiment of the present invention. The common source transistor apparatus 500 includes a plurality of common source transistor units 110, the isolation ring 120 and the substrate ring 130.

Each of the common source transistor unit 110 includes the diffusion area 140, the poly-silicon gates LV1˜LV4 and HV1˜HV6 and the source/bulk ring 150 illustrated in FIG. 1 and are not labeled in FIG. 5. The configuration and operation of these components are identical to those illustrated in FIG. 1 and are not described herein.

In the present embodiment, the amount of the common source transistor units 110 is larger than 1 and the common source transistor units 110 can be arranged to be an array so as to be surrounded by the isolation ring 120, in which the substrate ring 130 further surrounds the isolation ring 120.

Reference is now made to FIG. 6. FIG. 6 illustrates a layout diagram of a common source transistor apparatus 600 that includes a low voltage transistor and a high voltage transistor disposed independently according to some approaches. The common source transistor apparatus 600 includes a plurality of low voltage transistor units 610, a low voltage isolation ring 620 and a low voltage substrate ring 630 corresponding to the low voltage transistor. The common source transistor apparatus 600 further includes a plurality of high voltage transistor units 640, a high voltage isolation ring 650 and a high voltage substrate ring 660 corresponding to the high voltage transistor.

In some approaches, the low voltage transistor units 610 and the high voltage transistor units 640 are disposed independently. The low voltage transistor units 610 and the high voltage transistor units 640 include independent poly-silicon gates, independent diffusion areas and independent source/bulk rings (not illustrated) of their own. The isolation ring 620 surrounds the low voltage transistor units 610 and is surrounded by the low voltage substrate ring 630. On the other hand, the high voltage isolation ring 650 surrounds the high voltage transistor units 640 and is surrounded by the substrate ring 660.

Comparing to the common source transistor apparatus 500 in FIG. 5, the common source transistor apparatus 600 in FIG. 6 has a larger area. Further, the area that the high voltage transistor units 640 correspond to has a temperature higher than the temperature of the area that the low voltage transistor units 610 correspond to. The temperature distribution of the whole common source transistor apparatus 600 is therefore uneven. When the amount of the low voltage transistor units 610 and the high voltage transistor units 640 included in the common source transistor apparatus 600 is larger, the larger area and the more uneven distribution of the temperature are obtained.

In a numerical example, the common source transistor apparatus 500 in FIG. 5 includes 24 common source transistor units 110 arranged as an array of 3×8 (i.e., 3 units along the X-axis and 8 units along the Y-axis). The amount of the poly-silicon gates corresponding to the low voltage is 104. The amount of the poly-silicon gates corresponding to the high voltage is 106.

The length along the X-axis of the common source transistor apparatus 500 is 1044.04 micrometers (μm). The width along the Y-axis of the common source transistor apparatus 500 is 1079.4 micrometers. The area of the common source transistor apparatus 500 is 1.127 square millimeters (mm²).

The common source transistor apparatus 600 in FIG. 6 includes 24 low voltage transistor units 610 arranged as an array of 3×8 (i.e., 3 units along the X-axis and 8 units along the Y-axis). The common source transistor apparatus 600 further includes 24 high voltage transistor units 640 arranged as an array of 3×8 (i.e., 3 units along the X-axis and 8 units along the Y-axis). The amount of the poly-silicon gates corresponding to the low voltage is 104. The amount of the poly-silicon gates corresponding to the high voltage is 106.

The length along the X-axis of the common source transistor apparatus 600 is 1117.16 micrometers (μm). The width along the Y-axis of the common source transistor apparatus 600 is 1079.4 micrometers. The area of the common source transistor apparatus 600 is 1.206 square millimeters (mm²).

As a result, comparing to the common source transistor apparatus 600 in other approaches, the area of the common source transistor apparatus 500 of the present invention drops 6.5%.

It is appreciated that the embodiments described above are merely an example. In other embodiments, it is appreciated that many modifications and changes may be made by those of ordinary skill in the art without departing, from the spirit of the invention.

In summary, the common source transistor apparatus of the present invention integrates poly-silicon gates of low voltage transistors and high voltage transistors in the same diffusion area so as to be surrounded by a source/bulk ring to form a common source transistor unit. Only one isolation ring and one substrate ring are required to surround the common source transistor unit. As a result, such a configuration not only has a smaller area but also has a more even temperature distribution.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. A common source transistor apparatus, comprising:
a common source transistor unit comprising:
a diffusion area comprising a plurality of source/bulk areas and a plurality of drain areas disposed in an interlaced manner; and
a plurality of poly-silicon gates traversing laterally across the diffusion area, each disposed between one of the source/bulk areas and one of the drain areas and comprising:
a low-voltage gate part comprising 2N low voltage poly-silicon gates disposed neighboring to each other; and
a first high-voltage gate part and a second high-voltage gate part, the first high-voltage gate part disposed at a first side of the low-voltage gate part and having one of the source/bulk areas disposed between the first high-voltage gate part and the low-voltage gate part and the second high-voltage gate part disposed at a second side of the low-voltage gate part and having one of the source/bulk areas disposed between the second high-voltage gate part and the low-voltage gate part, wherein each of the first high-voltage gate part and the second high-voltage gate part comprises N+1 high-voltage poly-silicon gates disposed neighboring to each other; and
a source/bulk ring disposed to surround the diffusion area and the poly-silicon gates and electrically coupled to the source/bulk areas to receive a source/bulk voltage;
an isolation ring disposed to surround the common source transistor unit to receive an isolation voltage; and
a substrate ring disposed to surround the isolation ring to receive a substrate voltage.

2. The common source transistor apparatus of claim 1, wherein N is 2, the low-voltage gate part comprises four low voltage poly-silicon gates, the first high-voltage gate part comprises three first high voltage poly-silicon gates and the second high-voltage gate part comprises three second high voltage poly-silicon gates.

3. The common source transistor apparatus of claim 1, wherein the low-voltage gate part forms a low voltage transistor with the corresponding source/bulk areas and the corresponding drain areas, the first high-voltage gate part and the second high-voltage gate part form a high voltage transistor with the corresponding source/bulk areas and the corresponding drain areas, and the low voltage transistor and the high voltage transistor share a source.

4. The common source transistor apparatus of claim 3, wherein a level of each the source/bulk voltage, the isolation voltage and the substrate voltage corresponds to an operation voltage of the high voltage transistor.

5. The common source transistor apparatus of claim 3, wherein the low voltage transistor has an operation voltage of 5 volts and the high voltage transistor has an operation voltage 20 volts.

6. The common source transistor apparatus of claim 1, wherein the diffusion area is formed on a well area, the well area, the source/bulk ring and the isolation ring are formed on a substrate and the substrate ring is disposed outside of the substrate.

7. The common source transistor apparatus of claim 6, wherein the substrate corresponds to a first type dopant, the well area corresponds to a second type dopant, the diffusion area corresponds to the first type dopant and each of the source/bulk areas and the drain areas is an ion implantation area corresponding to the first type dopant and disposed in a doping area comprised by the diffusion area and corresponding to the second type dopant, wherein each of the first type dopant and the second type dopant is one of a P-type dopant and an N-type dopant.

8. The common source transistor apparatus of claim 7, wherein each of the source/bulk ring, the isolation ring and the substrate ring comprises a bottom part and a planting part disposed above the bottom part, the bottom part and the planting part of each of the source/bulk ring and the substrate ring correspond to the second type dopant, and the bottom part and the planting part of the isolation ring correspond to the first type dopant.

9. The common source transistor apparatus of claim 8, wherein an isolation structure is disposed at each of two sides of the planting part of each of the source/bulk ring, the isolation ring and the substrate ring.

10. The common source transistor apparatus of claim 1, wherein the common source transistor apparatus comprises a plurality of common source transistor unit arranged to be an array so as to be surrounded by the isolation ring.
